(19) United States
(12) Patent Application Publication
(10) Pub. No.: US 2026/0282707 A1
(43) Pub. Date: Sep. 17, 2026

(54) METHOD OF MANUFACTURING A DISPLAY DEVICE, DISPLAY DEVICE, AND ELECTRONIC DEVICE

(71) Applicant: SAMSUNG DISPLAY CO., LTD., YONGIN-SI (KR)

(72) Inventors: Beom Gyu CHOI, Yongin-si (KR); Ki Hyun KIM, Yongin-si (KR); Myung Sun JI, Yongin-si (KR)

(21) Appl. No.: 19/569,029

(22) Filed: Mar. 17, 2026

(30) Foreign Application Priority Data
Mar. 17, 2025 (KR) 10-2025-0033906

(51) Int. Cl. H10K 59/80

(52) U.S. Cl. CPC H10K 59/8722

(57) ABSTRACT

A method of manufacturing a display device includes forming a protective film on a first surface of coated glass, attaching an adhesive layer to a second and opposite surface of the coated glass, attaching a display panel to the adhesive layer, and integrally cutting the coated glass, the adhesive layer, and the display panel in a single pass.

### CROSS-REFERENCE TO RELATED APPLICATIONS

This application claims priority under 35 U.S.C. § 119 to and benefits from Korean Patent Application No. 10-2025-0033906 filed on Mar. 17, 2025 in the Korean Intellectual Property Office, the entire disclosure of which is incorporated by reference herein.

### TECHNICAL FIELD

The disclosure relates generally to a method of manufacturing a display device, the display device, and an electronic device.

### DISCUSSION OF RELATED ART

With the recent interest in information displays, research and development of display devices and electronic devices including the same has been ongoing.

### SUMMARY

Embodiments of the disclosure are to simplify a process of manufacturing a display device and improve an outline tolerance of the display device.

An embodiment of the disclosure provides a method of manufacturing a display device. The method includes forming a protective film on a first surface of coated glass, attaching an adhesive layer to a second surface of the coated glass, attaching a display panel to the adhesive layer, and simultaneously cutting the coated glass, the adhesive layer, and the display panel as a single stack.

The coated glass may include glass and a coated layer disposed on the glass.

The coated layer may overlap a first surface and a side surface of the glass.

The adhesive layer may be adhered to a second and opposite surface of the glass.

The protective film may be formed on the coated layer.

A side surface of the glass may be disposed inward relative to a side surface of the coated layer.

A side surface of the glass may be disposed inward relative to a cut surface of the coated glass.

The first surface and the second surface of the glass may be major surfaces.

The first surface and the second surface of the coated glass may be major surfaces.

An embodiment of the disclosure provides a display device including a display panel, coated glass disposed on the display panel, and an adhesive layer disposed between the display panel and the coated glass. An outer surface of the display panel, an outer surface of the coated glass, and an outer surface of the adhesive layer are aligned with each other.

The coated glass may include glass and a coated layer on the glass.

The glass may be disposed between the coated layer and the adhesive layer.

The coated layer may contact a first surface and a side surface of the glass.

The adhesive layer may contact a second and opposite surface of the glass.

A side surface of the glass may be disposed inward relative to a side surface of the coated layer.

An embodiment of the disclosure provides an electronic device including the display device manufactured by the method of manufacturing the display device.

The electronic device may also include a processor. The display device may include pixels. The display device may display an image via the pixels under control of the processor.

The display device of the electronic device may also include a coated glass having a first surface opposite a second surface, a protective film disposed on the first surface of the coated glass, and a display panel attached to the second surface of the coated glass by an adhesive layer. The pixels may be disposed in the display panel.

The coated glass may include glass and a coated layer disposed on the glass.

Side surfaces of the coated glass, the adhesive layer, and the display panel may be aligned with each other in a plan view corresponding to a thickness direction of the display device.

### BRIEF DESCRIPTION OF THE DRAWINGS

The above and other features of the disclosure will become more apparent by describing in further detail embodiments thereof with reference to the accompanying drawings, in which:

FIG. 1 is an example cross-sectional view of a display device according to an embodiment;

FIGS. 2-9 are respective example cross-sectional views illustrating the sequence of a method of manufacturing a display device according to an embodiment;

FIG. 10 is a schematic plan view of a display panel according to an embodiment;

FIG. 11 is a block diagram of an electronic device according to an embodiment; and

FIG. 12 shows schematic views of various embodiments of an electronic device.

### DETAILED DESCRIPTION

Herein, some example embodiments of the disclosure will be described in further detail with reference to the accompanying drawings. It is noted that in the following description, the parts desirable to understand the operation according to the disclosure will be described, and descriptions of other parts may be omitted in order to not obscure the gist of the disclosure. The disclosure is not necessarily limited to the embodiments described herein and may be embodied in other forms. The embodiments described herein are provided to explain the disclosure in further detail so as to enable those skilled in the art to readily implement the technical idea of the disclosure.

Throughout the specification, in a case in which a portion is “connected” to another portion, the case includes not only a case in which the portion is connected (e.g., directly connected) but also a case in which the portion is indirectly connected to one or more other elements disposed therebetween. Terms used herein are for describing specific embodiments and are not necessarily intended to limit the disclosure. Throughout the specification, in a case in which a certain portion “includes,” the case means that the portion may further include another component without excluding another component unless otherwise stated. “At least any one of X, Y, and Z” and “at least any one selected from a group consisting of X, Y, and Z” may be interpreted as one X (e.g., a single X), one Y (e.g., a single Y), one Z (e.g., a single Z), or any combination of two or more of X, Y, and Z (for example, XYZ, XY, YZ, and ZZ). Here, “and/or” includes all combinations of one or more of corresponding configurations.

Herein, terms such as “first” and “second” may be used to describe various components, but these components are not necessarily limited to these terms. These terms are used to distinguish a component from another component. Therefore, a “first” component may refer to a second component in a range without departing from the scope disclosed herein.

Spatially relative terms, such as “under,” “on,” and the like may be used for descriptive purposes, thereby describing a relationship between an element or feature and another element(s) or feature(s) as shown in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and, thus, the spatially relative terms used herein are interpreted according thereto.

Various embodiments are described with reference to drawings schematically illustrating example or ideal embodiments. Accordingly, it will be expected that shapes may vary, for example, according to tolerances and/or manufacturing techniques. Therefore, the embodiments disclosed herein are not necessarily to be construed as being limited to shown specific shapes, and are to be interpreted as including, for example, changes in shapes that may occur as a result of manufacturing. As described above, the shapes shown in the drawings might not show actual shapes of areas of a device, and the embodiments are not necessarily limited thereto. Hereinafter, a display device according to embodiments of the disclosure will be described with reference to the accompanying drawings.

While each drawing may represent one or more particular embodiments of the present disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the disclosure, for example, to allow for manufacturing limitations and the like.

Embodiments of the disclosure provide a method of manufacturing a display device as well as the display device manufactured by the method and an electronic device that includes the display device, where each of a coated glass, and adhesive layer and a display panel are cut in a single pass (or simultaneously in a single cut step). The resultant is a display device where the glass may be recessed inward as compared to a coated layer, adhesive, or the display panel, where the side surfaces of each of these layers are aligned with each other, and where the tolerance of the cut line is improved.

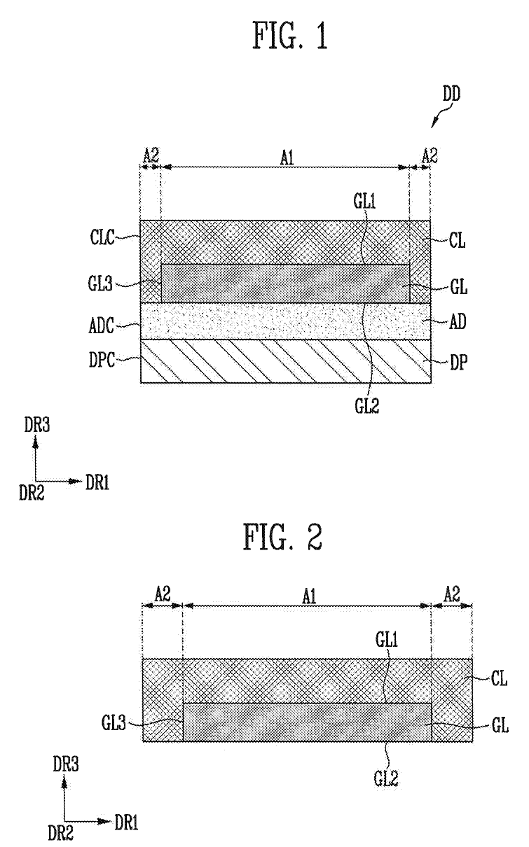

FIG. 1 is an example cross-sectional view of a display device DD according to an embodiment.

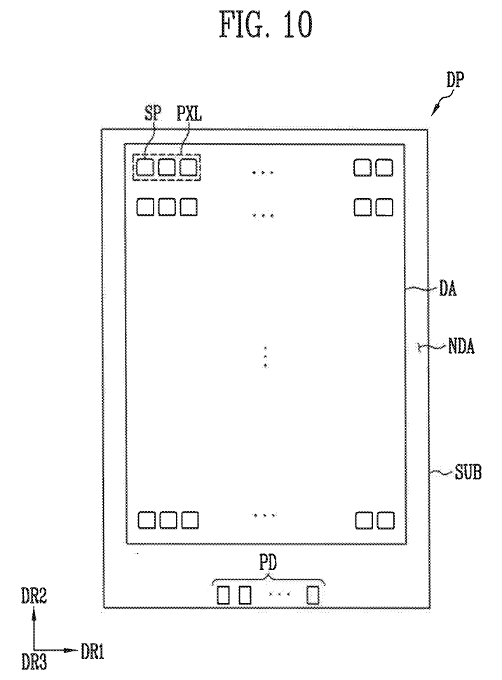

Referring to FIG. 1, the display device DD may include a display panel DP, coated glass CL and GL (or a combination of the glass GL and the coated layer CL), and/or an adhesive layer AD. A detailed description of the display panel DP will be described below with reference to FIG. 10.

The coated glass CL and GL may be arranged (or ‘disposed’) on the display panel DP. The coated glass CL and GL may be attached to the display panel DP by the adhesive layer AD.

The coated glass CL and GL may include at least one piece of glass GL and a coated layer CL (or ‘resin’) coated on the glass GL. The glass GL may be arranged between the adhesive layer AD and the coated layer CL. A first surface (or first major surface) GL1 of the glass GL may contact the coated layer CL, and a second and opposite surface (or second major surface) GL2 of the glass GL may contact the adhesive layer AD.

The coated layer CL may cover (or ‘overlap’) the first surface GL1 and a side surface GL3 of the glass GL. The coated layer CL may abut the first surface GL1 and the side surface GL3 of the glass GL. In an example, the side surface GL3 of the glass GL may be located inward (or towards the center of the device) from a side surface (or an outer surface or a cut surface) CLC of the coated layer CL. The glass GL may constitute a cover window of the display device or may be a polarizing plate.

The coated layer CL may include a first area A1 arranged on the first surface GL1 of the glass GL and a second area A2 surrounding the first area A1. The second area A2 may cover the side surface GL3 of the glass GL. A thickness of the first area A1 in a third direction DR3 may be less than a thickness of the second area A2 in the third direction DR3.

The adhesive layer AD may be arranged between the display panel DP and the coated glass CL and GL. The adhesive layer AD may serve to bond the display panel DP to the coated glass CL and GL. The adhesive layer AD may be arranged between the display panel DP and the glass GL. A surface of the adhesive layer AD may contact an upper surface of the display panel DP, and another surface of the adhesive layer AD may contact the second and opposite surface GL2 of the glass GL.

The adhesive layer AD may be arranged between the display panel DP and the second area A2 of the coated layer CL. A surface of the adhesive layer AD may contact the upper surface of the display panel DP, and another surface of the adhesive layer AD may contact the second area A2 of the coated layer CL.

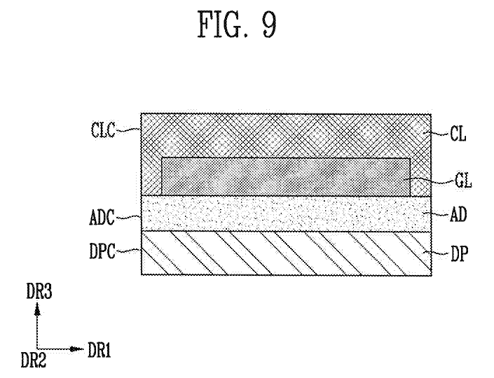

In an embodiment, an outer surface (or ‘a cut surface’) DPC of the display panel DP, the outer surface (or ‘the cut surface’) CLC of the coated glass CL and GL (or ‘the coated layer CL’), and/or an outer surface (or a cut surface) ADC of the adhesive layer AD may be aligned with each other. For example, the display panel DP, the coated glass CL and GL, and/or the adhesive layer AD may be cut integrally (or simultaneously) in the same process (or in a single pass of a cutting tool so that each of the coated glass, the adhesive layer and the display panel are simultaneously cut as a single stack). The term ‘single pass’ means a single pass of a cutting tool so that each element, including the display panel DP, the adhesive layer AD and the coated glass CL and GL is cut with a same, single pass of the cutting tool in a single step. This not only improves manufacturing productivity, but results in the side edge of each of the display panel DP, the adhesive layer AD and the coated glass CL and GL layers to be aligned with each other and so tolerances of the side edge of the display device can be minimized. Processes may be simplified by reducing the number of cutting processes compared to the number of processes in which the display panel DP and the coated glass CL and GL are each cut separately and then attached, and the outline tolerance of the display device DD may also be improved. A detailed description thereof will be described below with reference to FIGS. 2-9.

Therefore, the single pass cut simplifies the manufacturing process while also improving tolerances of the side edge of the display device. As a result, manufacturing costs and be reduced and the display device and the electronic device can have an improved design.

FIGS. 2-9 are example cross-sectional views illustrating the sequence of a manufacturing method of a display device according to an embodiment. FIGS. 2-9 are example cross-sectional views illustrating the manufacturing method of the display device DD of FIG. 1, and are shown briefly for ease of explanation. To the extent that an element is not described in detail with respect to this figure, it may be understood that the element is at least similar to a corresponding element that has been described elsewhere within the present disclosure..

Referring to FIG. 2, the coated glass CL and GL may first be prepared. The coated glass CL and GL may include at least one piece of glass GL and the coated layer CL formed on the glass GL. In an example, the coated layer CL may be coated on the first surface GL1 and the side surface GL3 of the glass GL. The coated layer CL may cover the first surface GL1 and the side surface GL3 of the glass GL.

The coated layer CL may include the first area A1 formed on the first surface GL1 of the glass GL and the second area A2 formed on the side surface GL3 of the glass GL. The second area A2 may surround the first area A1. A thickness of the second area A2 in the third direction DR3 may be greater than a thickness of the first area A1 in the third direction DR3.

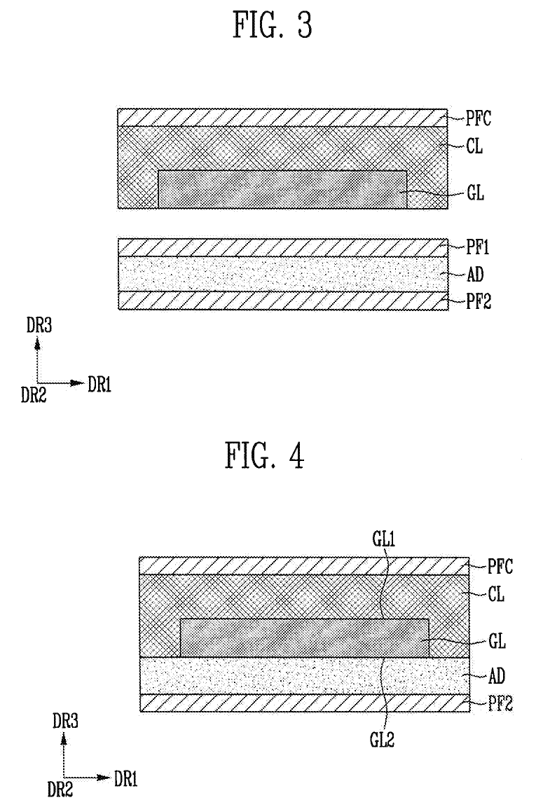

Referring to FIG. 3, a coating protective film PFC may then be formed or attached on a surface of the coated glass CL and GL, and the adhesive layer AD may be prepared. The coating protective film PFC may be arranged on the coated layer CL. The coated layer CL may be arranged between the glass GL and the coating protective film PFC.

A first protective film PF1 may be attached to a surface of the adhesive layer AD, and a second protective film PF2 may be attached to another surface of the adhesive layer AD. The adhesive layer AD may be arranged between the first protective film PF1 and the second protective film PF2.

Referring to FIG. 4, the first protective film PF1 may then be removed and the adhesive layer AD may be attached to another surface of the coated glasses CL and GL. A surface of the adhesive layer AD may contact the second surface GL2 of the glass GL. A surface of the adhesive layer AD may be at least partially in contact with the coated layer CL.

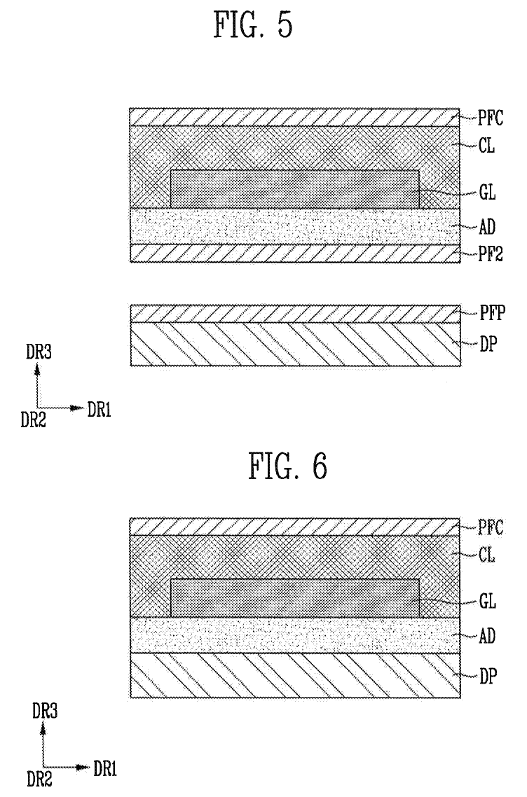

Referring to FIG. 5, subsequently, the display panel DP may be prepared. A display protective film PFP may be formed on or attached to a surface of the display panel DP.

Referring to FIG. 6, the adhesive layer AD may then be attached to a surface of the display panel DP. After the display protective film PFP attached to the display panel DP is removed, and the second protective film PF2 attached to the adhesive layer AD is removed, the adhesive layer AD may be attached to the display panel DP. A surface of the adhesive layer AD may be in contact with the display panel DP, and another surface of the adhesive layer AD may be in contact with the coated glass CL and GL. The display panel DP and the coated glass CL and GL may be coupled by the adhesive layer AD.

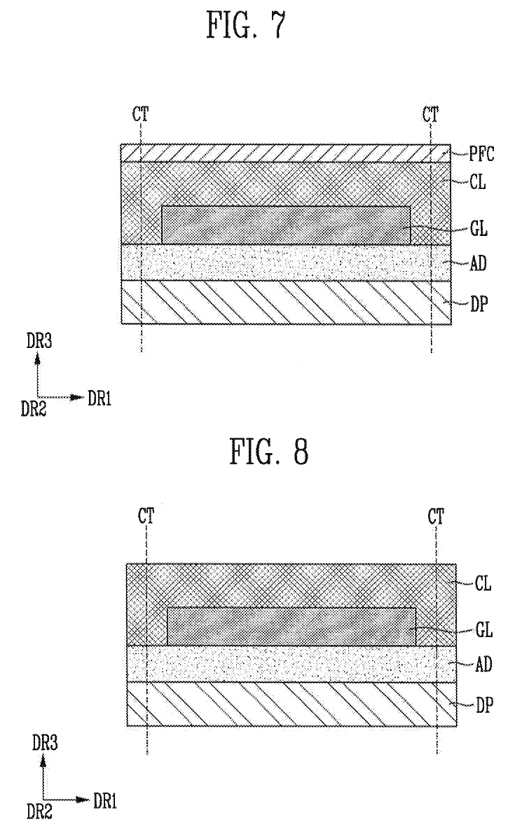

Referring to FIGS. 7-9, subsequently, the coating protective film PFC, the coated glass CL and GL, the adhesive layer AD, and/or the display panel DP are cut along line CT. The coated glass CL and GL, the adhesive layer AD, and the display panel DP may be cut as a whole (or simultaneously) in the same process (i.e., as a single stack or in a single pass of a cutting tool). The processes may be simplified by reducing the number of cutting processes compared to the number of processes in which the display panel DP and the coated glass CL and GL are each separately cut and then attached. As a result, the outline tolerance of the display device DD may be improved. As the coated glass CL and GL, the adhesive layer AD, and/or the display panel DP are cut simultaneously, the cut surface CLC of the coated glass CL and GL (or the coated layer CL), the cut surface ADC of the adhesive layer AD, and/or the cut surface DPC of the display panel DP may be aligned with each other along a cut line CT.

In an embodiment, as shown in FIG. 7, the coating glass CL and GL, the adhesive layer AD, and/or the display panel DP may be cut with the coating protective film PFC attached to a surface of the coated glass CL and GL (or the coated layer CL). However, the disclosure is not necessarily limited thereto, and in accordance with an embodiment, the coating glass CL and GL, the adhesive layer AD, and/or the display panel DP may be cut after the coating protective film PFC is removed, as shown in FIG. 8.

In an embodiment, the coated glass CL and GL, the adhesive layer AD, and/or the display panel DP may be cut by, but is not necessarily limited to, laser machining or CNC (i.e., computer neural control) machining.

By cutting each of the display panel DP, the adhesive layer AD and the coated glass CL and GL as a single stack or in a single pass of a cutting tool, manufacturing productivity can be enhanced, side edges of each of these layer may be aligned with each other, and improved cutting tolerances can be achieved.

FIG. 10 is the schematic plan view of the display panel DP according to an embodiment.

Referring to FIG. 10, the display panel DP may include a display area DA and a non-display area NDA. The display panel DP may display images in the display area DA. The non-display area NDA may be arranged around the periphery of the display area DA.

The display panel DP may include a substrate SUB, sub-pixels SP, and pads PD.

The sub-pixels SP may be arranged in a display area DA on the substrate SUB. The sub-pixels SP may be arranged in a matrix format in a first direction DR1 and a second direction DR2 intersecting the first direction DR1. However, embodiments are not necessarily limited thereto. For example, the sub-pixels SP may be arranged in a zigzag pattern in the first direction DR1 and the second direction DR2. For example, the sub-pixels SP may be arranged in a PEN-TILE® pattern, where PEN-TILE® is a registered trademark of SAMSUNG and represents an arrangement of subpixels in which some subpixels are shared between neighboring pixels. The first direction DR1 may be a row direction and the second direction DR2 may be a column direction. A single pixel PXL may include at least two of the sub-pixels SP.

Pads PDs may be arranged in the non-display area NDA on the substrate SUB. The pads PDs may be electrically connected to the sub-pixels SP via interconnection lines.

The pads PD may interface the display panel DP to other components of the display device DD. In an embodiment, voltages and signals to operate the components included in the display panel DP may be provided through the pads PD from a driver integrated circuit.

In an embodiment, a circuit board may be electrically connected to the pads PD using a conductive adhesive member, such as an anisotropic conductive film. The circuit board may be a flexible circuit board or flexible film having a flexible material. The driver integrated circuit may be mounted on the circuit board and electrically connected to the pads PD.

In an embodiment, the display area DA may have various shapes. The display area DA may have perimeter having a closed loop which includes straight and/or curved sides. For example, the display area DA may have the shape of a polygon, a circle, a semicircle, an ellipse, or the like.

In an embodiment, the display panel DP may have a substantially flat display surface. In an embodiment, the display panel DP may have a display surface which may be at least partially rounded. In an embodiment, the display panel DP may be bendable, foldable, or rollable. In these cases, the display panel DP and/or the substrate SUB may include materials having flexible properties.

The display panel DP may include a substrate, display elements bonded to the substrate, at least one conductive line bonded to the substrate and electrically connected to the display elements, and/or a thin-film encapsulation layer.

The display elements may be arranged on the substrate, and may form multiple pixels. For example, the display elements may be arranged in a matrix format on the substrate to form the pixels of the display panel DP. In an example, the display elements may include, but are not necessarily limited to, an organic light emitting diode (OLED).

The conductive line may include at least one gate signal line or at least one data signal line. The conductive line may include gate signal lines and data signal lines. The gate signal lines and the data signal lines may be arranged in a matrix format, and the display elements may be aligned adjacent to intersections between the lines and electrically connected to the lines.

The thin-film encapsulation layer may overlap the substrate, the display elements, and/or the conductive line to prevent oxygen and moisture from entering from the outside. The thin-film encapsulation layer may be formed by stacking at least one organic layer and at least one inorganic layer alternately on each other. The uppermost layer exposed to the outside of the thin-film encapsulation layer may include an inorganic layer to prevent moisture permeation, but is not necessarily limited thereto.

The display device DD according to an embodiment may be applied to various electronic devices. An electronic device according to an embodiment includes the display device DD as described above, and may further include modules or devices having other additional functions in addition to the display device DD.

As a result, a display device where all of the constituent layers the display panel DP, the adhesive layer AD and the coated glass CL and GL may be aligned with each other where the tolerances of the cutting may be improved.

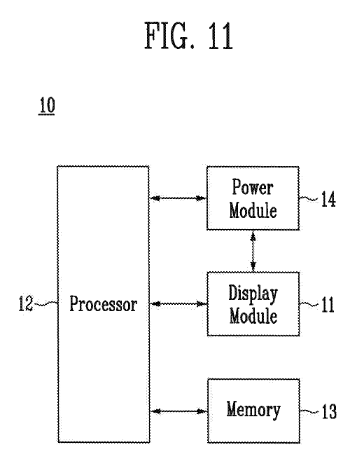

FIG. 11 is a block diagram of an electronic device 10 according to an embodiment. Referring to FIG. 11, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. In case that the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to the above-described embodiments. In terms of functionality, some of the individual modules included in a module may be included in the display device and others may be provided separately from the display device. For example, the display module 11 may be included in the display device, whereas the processor 12, the memory 13, and the power module 14 may not be included in the display device and may instead be provided separately in the electronic device 10.

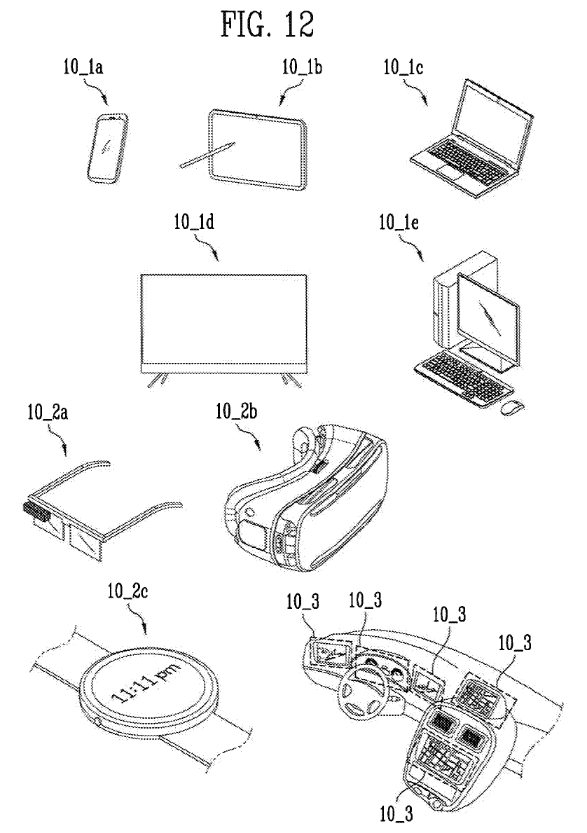

FIG. 12 shows schematic views of various embodiments of an electronic device.

Referring to FIG. 12, various types of electronic devices to which embodiments of the display device are applied may include a smartphone 10_1a, a tablet 10_1b, a laptop computer 10_1c, a television (TV) 10_1d, and a computer monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) arranged in an instrument cluster, a center fascia, a dashboard of a vehicle, and a room mirror display.

According to the embodiments as described above, the display panel, the coated glass, and/or the adhesive layer may be cut integrally (or simultaneously as a single stack or in a single pass of a cutting instrument) in the same process to thereby simplify the processes by reducing the number of cutting processes and improve the outline tolerance of the display device. Accordingly, manufacturing productivity is enhanced, side edges of the constituent layers are aligned with each other, and cutting tolerances are reduced.

It will be apparent to those skilled in the art which various modifications may be made to the above-described embodiments of the disclosure without departing from the spirit or scope of the disclosure. Thus, it is intended which the disclosure cover all such modifications provided they come in the scope of the appended claims and their equivalents.

What is claimed is:

1. A method of manufacturing a display device, the method comprising:
providing a coated glass having a first surface opposite a second surface;
forming a protective film on the first surface of coated glass;
attaching an adhesive layer to the second surface of the coated glass;
attaching a display panel to the adhesive layer; and
simultaneously cutting the coated glass, the adhesive layer, and the display panel as a single stack.

2. The method of claim 1, wherein the coated glass comprises:
glass; and
a coated layer disposed on the glass.

3. The method of claim 2, wherein the coated layer covers a upper surface and a side surface of the glass.

4. The method of claim 2, wherein the adhesive layer is adhered to a lower surface of the glass.

5. The method of claim 2, wherein the protective film is formed on the coated layer.

6. The method of claim 2, wherein a side surface of the glass is disposed inward relative to a side surface of the coated layer.

7. The method of claim 2, wherein a side surface of the glass is disposed inward relative to a cut surface of the coated glass.

8. The method of claim 4, wherein
the coated layer covers a upper surface and a side surface of the glass, and
the upper surface and the lower surface of the glass are major surfaces.

9. The method of claim 1, wherein the first surface and the second surface of the coated glass are major surfaces.

10. A display device, comprising:
a display panel;
coated glass disposed on the display panel; and
an adhesive layer disposed between the display panel and the coated glass,
wherein an outer surface of the display panel, an outer surface of the coated glass, and an outer surface of the adhesive layer are aligned with each other.

11. The display device of claim 10, wherein the coated glass comprises:
glass; and
a coated layer disposed on the glass.

12. The display device of claim 11, wherein the glass is disposed between the coated layer and the adhesive layer.

13. The display device of claim 11, wherein the coated layer contacts a first surface and a side surface of the glass.

14. The display device of claim 11, wherein the adhesive layer contacts a second and opposite surface of the glass.

15. The display device of claim 11, wherein a side surface of the glass is disposed inward relative to a side surface of the coated layer.

16. An electronic device, comprising the display device manufactured by the method of claim 1.

17. The electronic device of claim 16, further comprising:
a processor, wherein
the display device comprises a plurality of pixels, and the display device displays an image via the pixels under control of the processor.

18. The electronic device of claim 17, wherein
the display device further comprises:
a coated glass having a first surface opposite a second surface;
protective film disposed on the first surface of coated glass; and
a display panel attached to the second surface of the coated glass by an adhesive layer, and
the pixels are disposed in the display panel.

19. The electronic device of claim 18, wherein the coated glass comprises:
glass; and
a coated layer disposed on the glass.

20. The electronic device of claim 18, wherein side surfaces of the coated glass, the adhesive layer, and the display panel are aligned with each other in a plan view.
